(19) United States
(12) Patent Application Publication
(10) Pub. No.: US 2022/0297623 A1
(43) Pub. Date: Sep. 22, 2022

(54) REMAINING LIFETIME ESTIMATING METHOD, REMAINING LIFETIME ESTIMATING SYSTEM, AND VEHICLE

(71) Applicant: HONDA MOTOR CO., LTD., Tokyo (JP)

(72) Inventor: Takeru FUKUDA, Tokyo (JP)

(21) Appl. No.: 17/678,012

(22) Filed: Feb. 23, 2022

(30) Foreign Application Priority Data
Mar. 16, 2021 (JP) 2021-042318

(51) Int. Cl. B60R 21/017; G07C 5/10; G07C 5/08

(52) U.S. Cl. CPC B60R 21/0173; G07C 5/10; G07C 5/0816

(57) ABSTRACT

A remaining lifetime estimating method includes a conversion step of converting a total elapsed time of an airbag into a total elapsed time Tb of the airbag at a predetermined temperature t, according to a formula based on the Arrhenius equation; a remaining use time calculation step of calculating a remaining use time Tx of the airbag by subtracting the total elapsed time Tb from a lifetime Ta of the airbag at the predetermined temperature t; a correction step of performing a correction to increase the remaining use time Tx on the basis of a predetermined value Tc proportional to a power supply time to a vehicle; a determination step of determining whether or not the remaining use time Tx corrected is equal to or less than a predetermined value; and a notification step of issuing a notification regarding the lifetime of the airbag.

This application is based on and claims the benefit of priority from Japanese Patent Application No. 2021-042318, filed on 16 Mar. 2021, the content of which is incorporated herein by reference.

### BACKGROUND OF THE INVENTION

### Field of the Invention

The present invention relates to a remaining lifetime estimating method, a remaining lifetime estimating system, and a vehicle.

### Related Art

Conventionally, various methods for estimating a remaining lifetime of a subject have been proposed. For example, Patent Document 1 discloses a technique for estimating the remaining lifetime of a capacitor in actual use whenever a predetermined time has elapsed. In this technique, a predetermined elapsed time in actual use is converted into an elapsed time at a predetermined temperature and the converted value is subtracted from the remaining lifetime. The time is converted on the basis of a proportional relation between the remaining lifetime at the predetermined temperature and the remaining lifetime in actual use. In other words, the remaining time is estimated by subtracting the use time proportional to a temperature during actual use from the lifetime.

Patent Document 1: Japanese Unexamined Patent Application, Publication No. 2003-243269

### SUMMARY OF THE INVENTION

However, the technique of Patent Document 1 is intended for mechanical and chemical deterioration during actual use, and does not address deterioration over time. Therefore, in order to address deterioration over time, there is a need to measure the temperature whenever a predetermined time has elapsed even when the system is not operating. This leads to an increased power consumption of the system, which is undesirable.

The present invention was made in view of the above, and has an object of providing a technique for precisely estimating the remaining lifetime of a subject, while suppressing the power consumption of the system.

(1) The present invention provides a remaining lifetime estimating method (for example, a remaining lifetime estimating method performed by a remaining lifetime estimating system 2 described below) for estimating a remaining lifetime of a subject (for example, an airbag 10 described below) installed in a device (for example, a vehicle 1 described below), the method including: a conversion step (for example, a conversion step performed by a converter 32 described below) of, whenever a predetermined time has elapsed, converting a total elapsed time from a start of a first-time use of the subject into a total elapsed time Tb from the start of the first-time use of the subject at a predetermined temperature t, according to a formula based on the Arrhenius equation; a remaining use time calculation step (for example, a remaining use time calculation step performed by a remaining use time calculator 33 described below) of calculating a remaining use time Tx of the subject by subtracting the total elapsed time Tb from a lifetime Ta of the subject at the predetermined temperature t; a correction step (for example, a correction step performed by a corrector 34 described below) of performing a correction to increase the remaining use time Tx on the basis of a predetermined value Tc proportional to a power supply time to the device; a determination step (for example, a determination step performed by a determiner 37 described below) of determining whether or not the remaining use time Tx corrected in the correction step is equal to or less than a predetermined value; and a notification step (for example, a notification step performed by a notifier 38 described below) of issuing a notification regarding the lifetime of the subject when it has been determined in the determination step that the corrected remaining use time Tx is equal to or less than the predetermined value.

(2) The remaining lifetime estimating method according to the above (1), wherein in the correction step, the correction to increase the remaining use time Tx may be performed by adding the predetermined value Tc to extend the lifetime Ta.

(3) The remaining lifetime estimating method according to the above (1) or (2), wherein the predetermined value Tc may be greater the lower the temperature of the subject when power is supplied to the device.

(4) The remaining lifetime estimating method according to any one of the above (1) to (3), wherein the correction step may have: an acquisition step (for example, an acquisition step performed by an acquirer 35 described below) of, whenever a predetermined time has elapsed, acquiring a temperature of the subject and a use time at that temperature when power is supplied to the device; and a correction processing step (for example, a correction processing step performed by a correction processor 36 described below) of, whenever a predetermined time has elapsed, acquiring the predetermined value Tc by converting the acquired use time using the acquired temperature into a use time at the predetermined temperature t according to a formula based on the Arrhenius equation, and, on the basis of the predetermined value Tc, performing the correction to increase the remaining use time Tx.

(5) The remaining lifetime estimating method according to the above (4), wherein the conversion step and the correction processing step may be performed when power starts to be supplied to the device, and the acquisition step may be performed after determination by the determination step, and is continuously performed until power stops being supplied to the device.

(6) The remaining lifetime estimating method according to the above (4) or (5), wherein a plurality of the subjects may be installed in the device, and in the acquisition step, temperatures of the plurality of subjects when power is supplied to the device may be acquired by multiplying a detected value of a reference temperature sensor (for example, an air conditioning temperature sensor 20 described below) installed in the device by constants determined in advance.

(7) In addition, the present invention provides a remaining lifetime estimating system (for example, a remaining lifetime estimating system 2 described below) for estimating a remaining lifetime of a subject (for example, an airbag 10 described below) installed in a device (for example a vehicle 1 described below), the remaining lifetime estimating system including: a converter (for example, a converter 32 described below) configured to, whenever a predetermined time has elapsed, convert a total elapsed time from a start of a first-time use of the subject into a total elapsed time Tb from the start of the first-time use of the subject at a predetermined temperature t, according to a formula based on the Arrhenius equation; a remaining use time calculator (for example, a remaining use time calculator 33 described below) configured to calculate a remaining use time Tx of the subject by subtracting the total elapsed time Tb from a lifetime Ta of the subject at the predetermined temperature t; a corrector (for example, a corrector 34 described below) configured to perform a correction to increase the remaining use time Tx on the basis of a predetermined value Tc proportional to a power supply time to the device; a determiner (for example, a determiner 37 described below) configured to determine whether or not the remaining use time Tx corrected in the correction step is equal to or less than a predetermined value; and a notifier (for example, a notifier 38 described below) configured to issue a notification regarding the lifetime of the subject when it has been determined in the determination step that the corrected remaining use time Tx is equal to or less than the predetermined value.

(8) The remaining lifetime estimating system according to the above (7), wherein the corrector may perform the correction to increase the remaining use time Tx by adding the predetermined value Tc to extend the lifetime Ta.

(9) The remaining lifetime estimating system according to the above (7) or (8), wherein the predetermined value Tc may be greater the lower the temperature of the subject when power is supplied to the device.

(10) The remaining lifetime estimating system according to any one of the above (7) to (9), wherein the corrector may have: an acquirer (for example, an acquirer 35 described below) configured to, whenever a predetermined time has elapsed, acquire a temperature of the subject and a use time at that temperature when power is supplied to the device; and a correction processor (for example, a correction processor 36 described below) configured to, whenever a predetermined time has elapsed, acquire the predetermined value Tc by converting the acquired use time using the acquired temperature into a use time at the predetermined temperature t according to a formula based on the Arrhenius equation, and, on the basis of the predetermined value Tc, perform the correction to increase the remaining use time Tx.

(11) The remaining lifetime estimating system according to the above (10), wherein the converter may perform the conversion when power starts to be supplied to the device, the correction processor may perform the correction when power starts to be supplied to the device, and the acquirer may perform the acquisition after determination by the determiner, and continuously performs the acquisition until power stops being supplied to the device.

(12) The remaining lifetime estimating system according to the above (10) or (11), wherein a plurality of the subjects may be installed in the device, and the acquirer may acquire temperatures of the plurality of subjects when power is supplied to the device by multiplying a detected value of a reference temperature sensor installed in the device by constants determined in advance.

(13) The present invention also provides a vehicle including the remaining lifetime estimating system according to any one of the above (7) to (12), wherein the subject is a vehicle body component, and the reference temperature sensor is an air conditioning temperature sensor.

(14) The vehicle according to the above (13), wherein the subject is a driver's seat airbag component and/or a passenger's seat airbag component.

According to the remaining life estimating method according to the above (1), whenever a predetermined time has elapsed, a total elapsed time from a start of a first-time use of the subject is converted into a total elapsed time Tb from the start of the first-time use of the subject at a predetermined temperature t, according to a formula based on the Arrhenius equation. In addition, a remaining use time Tx of the subject is calculated by subtracting the total elapsed time Tb from a lifetime Ta of the subject at the predetermined temperature t. Then, a correction to increase the remaining use time Tx is performed on the basis of a predetermined value Tc proportional to a power supply time to the device. In other words, according to the remaining lifetime estimating method as in the above (1), because deterioration of the subject is assumed to slow down when power is supplied to the vehicle due to operation of air conditioning, etc., a remaining use time Tx is first calculated on the basis of the Arrhenius equation, and a correction is performed to increase the remaining use time Tx on the basis of a predetermined value Tc that is acquired by measuring a temperature when power is supplied to the device whenever a predetermined time has elapsed.

Thus, a correction to increase the remaining use time is performed on the basis of the temperature and use time of the subject in actual use, and therefore the remaining lifetime of the subject can be estimated precisely. Therefore, the usable time of the subject can be established precisely, which as a result allows for an extension of the remaining lifetime during which safe use is possible. In addition, the correction is performed when power is supplied to the device, and therefore, unlike Patent Document 1, there is no need to measure the temperature whenever a predetermined time has elapsed even when the system is not operating in order to address deterioration over time. Therefore, according to the remaining lifetime estimating method as in the above (1), it is possible to precisely estimate the remaining lifetime of a subject, while suppressing the power consumption of the system.

According to the remaining lifetime estimating method as in the above (2), the remaining use time Tx can be increased by adding the predetermined value Tc to extend the lifetime Ta. Therefore, the effect of the remaining lifetime estimating method as in the above (1) can be achieved more reliably.

According to the remaining lifetime estimating method as in the above (3), the predetermined value Tc is set to be greater the lower the temperature of the subject when power is supplied to the device. Therefore, deterioration over time of the subject is more suppressed the lower the temperature, allowing for further improvement of the estimation precision of the remaining lifetime.

According to the remaining lifetime estimating method as in the above (4), whenever a predetermined time has elapsed, the correction to increase the remaining use time Tx is performed on the basis of the predetermined value Tc acquired by converting the use time at a temperature of the subject when power is supplied to the device into a use time at the predetermined temperature t according to a formula based on the Arrhenius equation. Therefore, the remaining use time Tx can be corrected on the same scale as the total elapsed time Tb, making it possible to more precisely estimate the remaining lifetime.

According to the remaining lifetime estimating method as in the above (5), the conversion into the total elapsed time Tb from the start of the first-time use of the subject at the predetermined temperature t based on the Arrhenius equation is performed when power starts to be supplied to the device. Likewise, the predetermined value Tc obtained by the conversion into the use time at the predetermined temperature t based on the Arrhenius equation is acquired when power starts to be supplied to the device. Further, the acquisition of the temperature of the subject and the use time at that temperature when power is supplied to the device is performed after determination by the determination step, and is continuously performed until power stops being supplied to the device. Thus, when the device is not operating, there is no need to count the temperature and time, and therefore the power consumption of the system can be more reliably suppressed.

According to the remaining lifetime estimating method as in the above (6), temperatures of the plurality of subjects when power is supplied to the device are acquired by multiplying a detected value of a reference temperature sensor installed in the device by constants determined in advance. Therefore, there is no need to provide a plurality of temperature sensors, which makes it possible to reduce costs. In the aforementioned Patent Document 1, the temperature of the capacitor is measured directly, and therefore a number of temperature sensors are required depending on the number of capacitors. With the remaining lifetime estimating method as in the above (6), however, this can be avoided with certainty.

According to the remaining lifetime estimating system as in the above (7) to (12), the same effects as the remaining lifetime estimating method as in the above (1) to (6) can be achieved.

According to the vehicle as in the above (13), the remaining lifetime estimating system as in any one of the above (7) to (12) is applied to a vehicle body component, and an air conditioning temperature sensor which the vehicle is already provided with can be used. Therefore, lifetime estimation of the vehicle body component is possible without adding sensors, which reduces costs.

According to the vehicle as in the above (14), the remaining lifetime estimating system as in any one of the above (7) to (12) can be applied to a driver's seat airbag component and a passenger's seat airbag component. Therefore, an effect of ensuring safety of these airbags can be achieved.

### BRIEF DESCRIPTION OF THE DRAWINGS

FIG. 1 is a perspective view of an interior of a vehicle according to an embodiment of the present invention;

FIG. 2 is a cross-sectional view of an airbag according to an embodiment of the present invention;

FIG. 3 is a functional block diagram illustrating a configuration of a remaining lifetime estimating system according to an embodiment of the present invention;

FIG. 4 illustrates a lifetime curve of an airbag;

FIG. 5 illustrates positions of an air conditioning temperature sensor and temperature measuring points of airbags of a vehicle according to an embodiment of the present invention;

FIG. 6 is a flowchart illustrating a sequence of processes of the remaining lifetime estimating system according to an embodiment of the present invention when an ignition is turned ON;

FIG. 7 is a flowchart illustrating a sequence of processes of the remaining lifetime estimating system according to an embodiment of the present invention when the ignition is turned OFF;

FIG. 8 illustrates a difference in temperature of an airbag between when the vehicle is parked and when the vehicle is running;

FIG. 9 illustrates temperatures when a vehicle has been parked all day and when the vehicle has been running;

FIG. 10 illustrates accumulated hours at measured temperatures when a vehicle has been parked all day and when the vehicle has been running; and

FIG. 11 explains a time conversion based on the Arrhenius equation.

### DETAILED DESCRIPTION OF THE INVENTION

An embodiment of the present invention is described with reference to the drawings.

A remaining lifetime estimating system according to the present embodiment applies the remaining lifetime estimating system according to the present invention to an estimation of a remaining lifetime of an airbag installed in an interior of a vehicle. When the vehicle is parked, the airbag is exposed to high temperatures and therefore deterioration of the airbag progresses, whereas when the vehicle is running (when power is supplied to the vehicle), operation of air conditioning, etc. lowers an interior temperature of the vehicle, slowing down deterioration of the airbag, and in this case the remaining lifetime estimating system according to the present embodiment performs a correction to increase the remaining use time, thereby extending the remaining lifetime. The remaining lifetime estimating method according to the present embodiment is realized by the remaining lifetime estimating system according to the present embodiment.

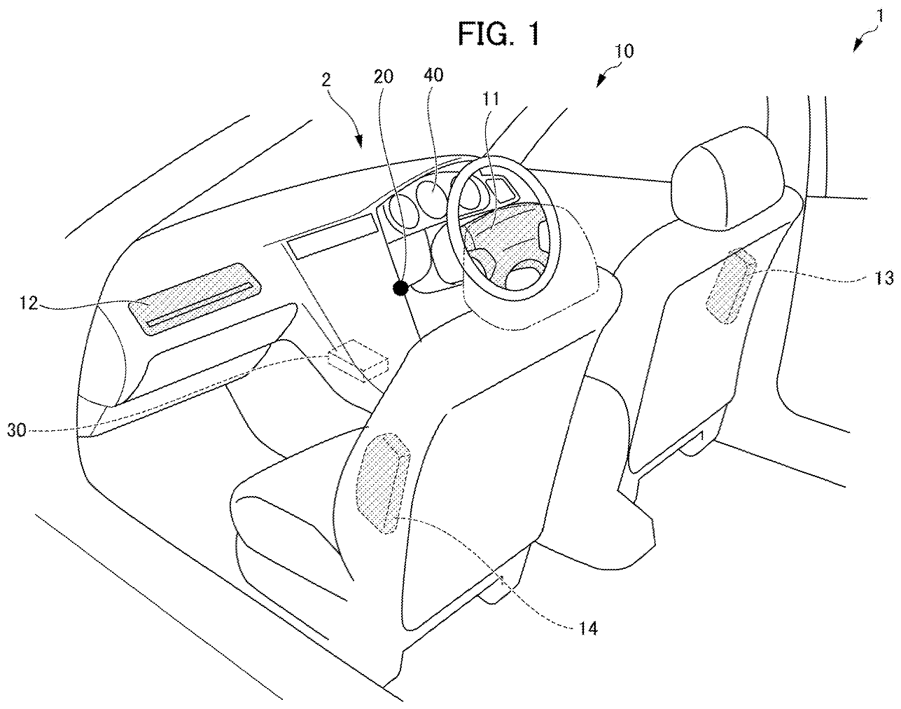

FIG. 1 is a perspective view of an interior of a vehicle 1 according to an embodiment of the present invention. As illustrated in FIG. 1, a vehicle 1 is provided with a remaining lifetime estimating system 2 according to the present embodiment, and has in its interior an airbag 10, an air conditioning temperature sensor 20, an ECU 30, and an airbag warning light 40. The airbag 10 is constituted by a plurality of airbags, and specifically has a driver's seat airbag 11, a passenger's seat airbag 12, a driver's seat side airbag 13, and a passenger's seat side airbag 14.

The driver's seat airbag 11, the passenger's seat airbag 12, the driver's seat side airbag 13, and the passenger's seat side airbag 14 are all electrically connected to the ECU 30 (illustration omitted). These airbags 11 to 14 are controlled by the ECU 30 when a collision of the vehicle 1 has been detected, whereby an inflator provided to each airbag 11 to 14 operates to generate a gas, which causes a bag-shaped bag fabric to inflate and expand. This protects occupants from the impact of the collision.

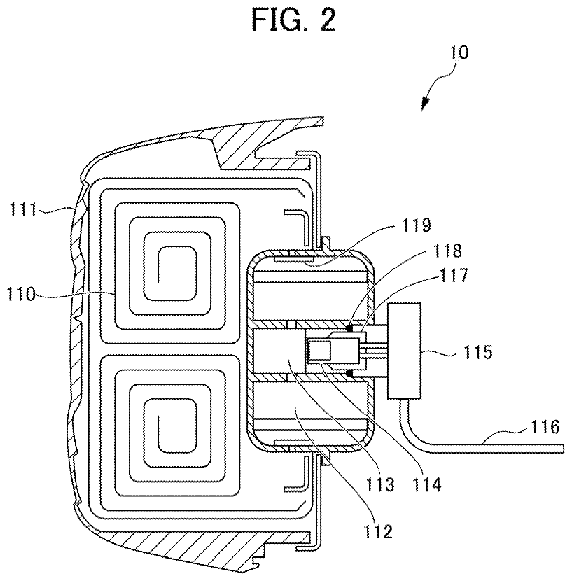

FIG. 2 is a cross-sectional view of the airbag 10 according to the present embodiment. The driver's seat airbag 11, the passenger's seat airbag 12, the driver's seat side airbag 13, and the passenger's seat side airbag 14 all have the same basic structure. As illustrated in FIG. 2, the airbag 10 includes a bag fabric 110, an airbag cover 111, a gas generant 112, an igniting agent 113, an explosive 114, a connector 115, a harness 116, a squib body 117, an O-ring 118, and a sealing tape (adhesive) 119.

Here, airbag components that deteriorate over time include, for example, the bag fabric 110, the gas generant 112 constituting the inflator, the O-ring 118, and the sealing tape 119, etc. As these airbag components deteriorate over time, the remaining lifetime estimating system 2 according to the present embodiment allows for precise estimation of the lifetime.

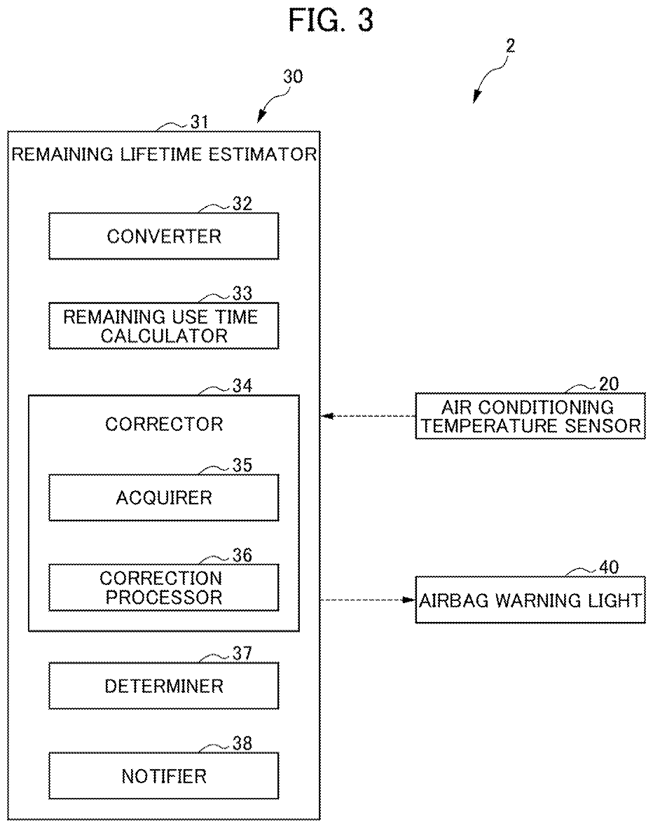

FIG. 3 is a functional block diagram of the remaining lifetime estimating system 2 according to an embodiment of the present invention. As illustrated in FIG. 3, the remaining lifetime estimating system 2 according to the present embodiment is composed of the ECU 30, the air conditioning temperature sensor 20, and the airbag warning light 40. The ECU 30 is provided with a remaining lifetime estimator 31.

As illustrated in FIG. 3, the remaining lifetime estimator 31 includes a converter 32, a remaining use time calculator 33, a corrector 34, a determiner 37, and a notifier 38. The corrector 34 includes an acquirer 35, and a correction processor 36. The remaining lifetime estimator 31 is electrically connected to the air conditioning temperature sensor 20 and the airbag warning light 40, receives a detection signal from the air conditioning temperature sensor 20, and transmits a control signal to the airbag warning light 40.

The converter 32 perform a conversion step in the remaining lifetime estimating method according to the present embodiment. The converter 32 first acquires a total elapsed time since a start of a first-time use of the airbag 10. This total elapsed time includes even an elapsed time while the vehicle 1 is parked and is not powered. Normally, this total elapsed time is the total time that has elapsed since the point in time when the vehicle 1 was shipped from a factory. This total elapsed time is acquired from a timer (illustration omitted), etc. provided to the vehicle 1 when power starts to be supplied to the vehicle 1 (when the ignition is turned ON).

The converter 32 converts the acquired total elapsed time from the start of the first-time use of the airbag 10 into a total elapsed time Tb from the start of the first-time use of the airbag at a predetermined temperature t, according to the following Formula (1) based on the Arrhenius equation. Below, this process is referred to as a conversion process. The Arrhenius equation represented by Formula (1) below is a time-temperature conversion rule, which allows for estimation of a deterioration behavior of a subject over a long elapsed time by manipulating the temperature instead of the time.

$$\begin{matrix}[ Math 1 ] & \\ \frac{{t}_{i} = {A}^{′} exp ( {E}_{a} / {RT}_{i} )}{{t}_{0} = {A}^{′} exp ( {E}_{a} / {RT}_{0} )} \to log {t}_{i} - log {t}_{0} = \frac{{E}_{a}}{2.303 R} ( \frac{1}{{T}_{i}} - \frac{1}{{T}_{0}} ) & Formula ( 1 )\end{matrix}$$

In Formula (1), tᵢ is an actual time (h), to is a conversion time (h), E_{α} is an activation energy intrinsic to a material (for example, 135.84 (kJ/mol) when the material of the airbag 10, which is the subject of the present embodiment, is PA66), Tᵢ is an actual absolute temperature (K), T₀ is a converted absolute temperature (K), and R is an ideal gas constant 8.31×10⁻³ kJ/mol/K.

The aforementioned predetermined temperature t is not particularly limited, and may be set to, for example, 107° C. The basis for the temperature of 107° C. is as follows. By carrying out a conversion using the aforementioned Arrhenius equation on the basis of a temperature and time distribution of a driver's seat airbag over 1 year acquired by the applicant, wherein a vehicle of a type that experiences the highest temperatures was parked outdoors in Death Valley in the United States of America, a place known for its extreme heat, a temperature and time frequency for 1 year in this actual environment becomes a result corresponding to 21.6 hours at a constant temperature of 107° C. These conversion results uses an activation energy value of 135.84 (kJ/mol), which is the activation energy value when the material of the airbag 10, which is the subject of the present embodiment, is PA66. In the present embodiment, the constant temperature 107° C. acquired as described above is set as the aforementioned predetermined temperature t.

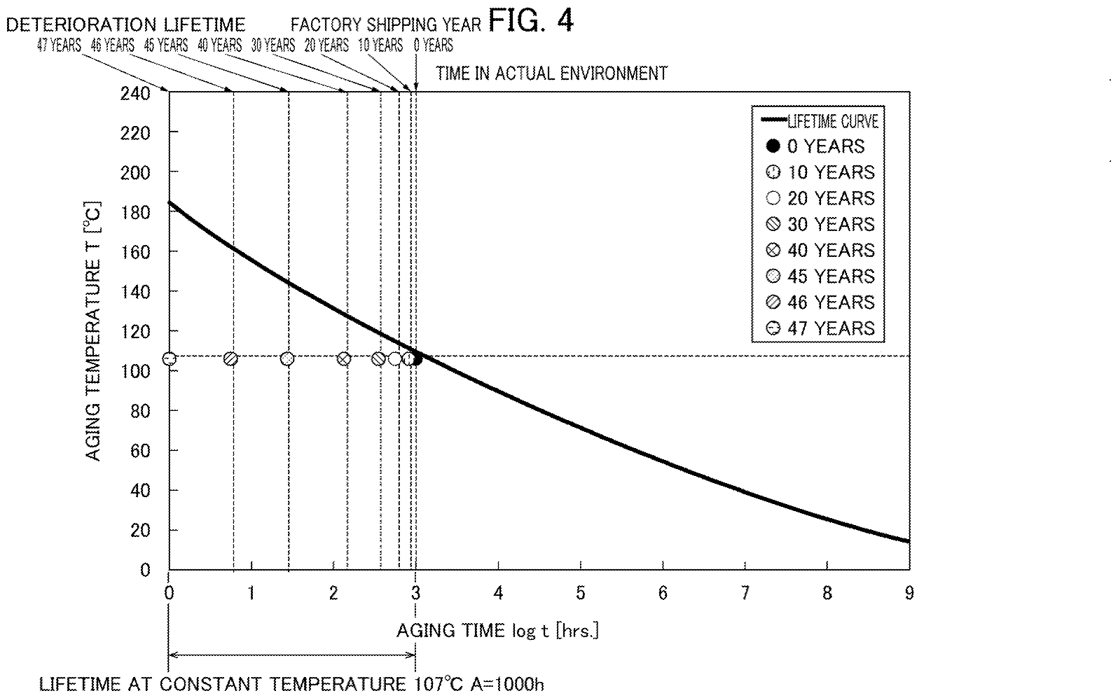

Here, FIG. 4 illustrates a lifetime curve of the airbag 10. The lifetime curve illustrated in FIG. 4 was made on the basis of mechanical performance retention (for example, a tensile strength retention of 90%) test results after a 3 to 4 level high-temperature aging test, with PA66 being used as the material of the airbag 10. FIG. 4 corresponds to a case wherein a conversion time when the constant temperature is 107° C. is calculated from the actual temperature at the time of parking and the annual temperature data of the accumulated time, and the actual number of years until the remaining lifetime becomes zero is plotted with an aging time at 107° C. In FIG. 4, the lower X-axis represents an aging time log t, the upper X-axis represents time in the actual environment, and the Y-axis represents an aging temperature T.

In FIG. 4, using the 107° C. temperature point of the lifetime curve of the airbag 10 as a starting point, the left side of this starting point can be defined as the remaining lifetime. As illustrated in FIG. 4, the aging time log t at this starting point is 3, and it can therefore be seen that t is 10³=1,000 hours. This means that the lifetime can be defined as 1,000 hours at a constant temperature of 107° C., and because the temperature and time frequency for 1 year in the aforementioned actual environment corresponds to 21.6 hours at the constant temperature of 107° C., it can be seen that the deterioration lifetime in the case of this material is 1,000/21.6≈47 years. In short, with this material, in an in-vehicle temperature environment of a vehicle of a type that experiences the highest temperatures being parked outdoors in the extremely hot area of Death Valley all day without running, the deterioration lifetime can be estimated to be 47 years.

The remaining lifetime decreases with the passage of time, and the lifetime ends when the remaining lifetime reaches zero. The above starting point is the factory shipping time of the vehicle 1, and a countdown to zero of the remaining lifetime starts from the factory shipping time, ending at 47 years. When the vehicle is parked, the vehicle interior becomes a high-temperature environment, and therefore deterioration of the airbag 10 progresses. Conversely, when the vehicle is running (when power is supplied to the vehicle), the in-vehicle temperature is lowered due air conditioning or opening of windows by occupants. This slows the deterioration progress of the airbag 10. In this regard, the remaining lifetime estimating system 2 according to the present embodiment has a feature of performing a correction to increase a remaining use time Tx on the basis of a predetermined value Tc proportional to the power supply time when the vehicle is running (when power is supplied to the vehicle). This feature is described further in a later paragraph.

Returning to FIG. 3, the converter 32 performs the aforementioned conversion process whenever a predetermined time has elapsed. This predetermined time is not particularly limited, and may be set to, for example, 1 hour.

In addition, the converter 32 performs the aforementioned conversion process when power starts to be supplied to the vehicle 1. In this way, the conversion process is not performed when the vehicle is parked (when power is not supplied to the vehicle), allowing for the power consumption of the system to be suppressed.

The remaining use time calculator 33 performs a remaining use time calculation step in the remaining lifetime estimating method according to the present embodiment. The remaining use time calculator 33 calculates a remaining use time Tx of the airbag 10 by subtracting the total elapsed time Tb at the predetermined temperature t converted by the aforementioned converter 32 from a lifetime Ta of the airbag 10 at the predetermined temperature t. The lifetime Ta of the airbag 10 is set in advance for an all-day outdoor parking environment with the highest high-temperature frequency. The lifetime Ta of the airbag 10 at the predetermined temperature t is determined in advance according to, for example, a formula based on the Arrhenius equation, and stored in a storage (illustration omitted) of the ECU 30.

The corrector 34 performs a correction step in the remaining lifetime estimating method according to the present embodiment. The corrector 34 performs a correction to increase the remaining use time Tx on the basis of the predetermined value Tc proportional to the power supply time to the vehicle 1. As described above, the corrector 34 includes an acquirer 35 and a correction processor 36. The corrector 34 performs the correction to increase the remaining use time Tx by subtracting the predetermined value Tc from the total elapsed time Tb at the predetermined temperature t converted by the aforementioned converter 32. Alternatively, the corrector 34 performs the correction to increase the remaining use time Tx by adding the predetermined value Tc to extend the lifetime Ta.

The lower the temperature of the airbag 10 when power is supplied to the vehicle 1, the greater the value to which the predetermined value Tc is set. The lower the temperature of the airbag 10 when power is supplied to the vehicle 1, the more the deterioration of the airbag 10 over time is slowed down, and therefore, the predetermined value Tc is set to a greater value to further increase the remaining use time Tx.

The predetermined value Tc is preferably obtained by converting the use time at a temperature of the airbag 10 when power is supplied to the vehicle 1 into a use time at the predetermined temperature t according to a formula based on the Arrhenius equation using the temperature when power is supplied. In order to obtain this predetermined value Tc, the corrector 34 includes the acquirer 35 and the correction processor 36.

The acquirer 35 performs an acquisition step in the remaining lifetime estimating method according to the present embodiment. The acquirer 35 acquires, whenever a predetermined time has elapsed, a temperature of the airbag 10 and a use time at that temperature when power is supplied to the vehicle 1. The temperature of the airbag 10 when power is supplied to the vehicle 1 and the use time at that temperature signify temperature and time frequency data. The acquired temperature and time frequency data is stored in the storage (illustration omitted) of the ECU 30.

After a determination by the determiner 37, the acquirer 35 acquires the temperature of the airbag 10 when power is supplied to the vehicle 1 and the use time at that temperature. The acquirer 35 continues to acquire the temperature of the airbag 10 when power is supplied to the vehicle 1 and the use time at that temperature until power stops being supplied to the vehicle 1. The predetermined time is not particularly limited, and may be set to, for example, 1 hour.

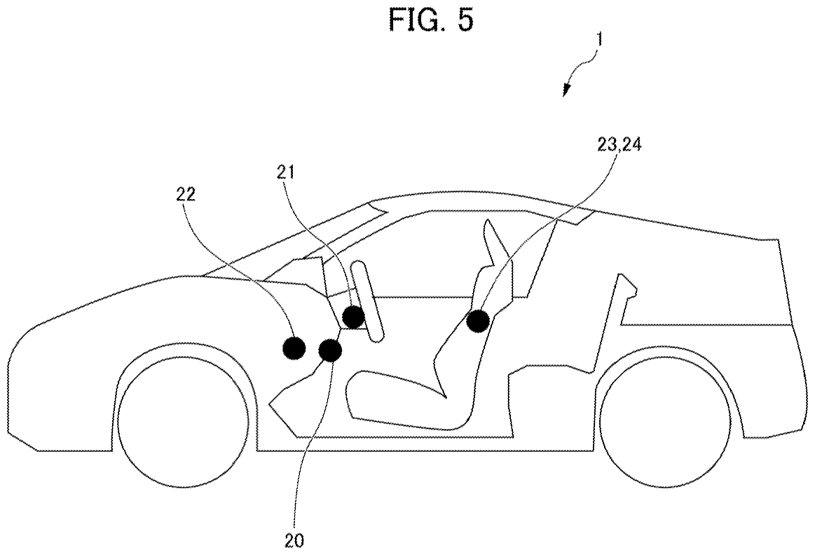

The acquirer 35 acquires the temperatures of the airbag 10 when power is supplied to the vehicle 1 by multiplying a detected value of the air conditioning temperature sensor 20 installed in the vehicle 1 by predetermined constants. FIG. 5 illustrates positions of the air conditioning temperature sensor 20 and temperature measuring points 21-24 of the airbags 11-14 of the vehicle 1 according to an embodiment of the present invention. As described above, in the present embodiment, the temperatures of the airbags 11-14 when power is supplied to the vehicle 1 are acquired by multiplying detected values of the air conditioning temperature sensor 20 installed in the vehicle 1 by predetermined constants. The constants are determined by experimentation in advance, wherein temperatures at the temperature measuring points 21-24 of the airbags 11-14 when power is supplied to the vehicle 1 are measured, and the constants are obtained from the ratio of the measured results to the detected values of the air conditioning temperature sensor 20.

For example, a temperature E1 of the driver's seat airbag 11 relative to a temperature D of the air conditioning sensor 20 is calculated by the following Formula (2), using a constant F1=1.149 obtained by experimentation in advance as described above.

[Math 2]

E1=1.149×D Formula (2)

Similarly, a temperature E2 of the passenger's seat airbag 12 relative to the temperature D of the air conditioning sensor 20 is calculated by the following Formula (3), using a constant F2=1.019 obtained by experimentation in advance as described above.

[Math 3]

E2=1.019×D Formula (3)

Similarly, a temperature E34 of the driver's seat side airbag 13 and the passenger's seat side airbag 14 relative to the temperature D of the air conditioning sensor 20 is calculated by the following Formula (4), using a constant F34=1.019 obtained by experimentation in advance as described above.

[Math 4]

E34=1.019×D Formula (4)

In this way, in the remaining lifetime estimating system 2 according to the present embodiment, the temperatures of the airbags 11-14 can be acquired by only the air conditioning temperature sensor 20. Therefore, by using the air conditioning temperature sensor 20 that the vehicle 1 is already provided with, estimation of the remaining lifetime of the airbag 10 is possible without adding a new temperature sensor.

Returning to FIG. 3, the correction processor 36 performs a correction processing step in the remaining lifetime estimating method according to the present embodiment. Whenever a predetermined time has elapsed, the correction processor 36 acquires the predetermined value Tc by converting the use time acquired by the aforementioned acquirer 35, using the temperature also acquired by the acquirer 35, into a use time at the predetermined temperature t according to a formula based on the Arrhenius equation. Then, on the basis of the predetermined value Tc acquired as described above, the correction processor 36 performs the correction to increase the remaining use time Tx. The predetermined time is not particularly limited, and may be set to, for example, 1 hour.

In addition, the correction processor 36 performs the correction to increase the remaining use time Tx when power starts to be supplied to the vehicle 1. In this way, the correction is not performed when the vehicle is parked (when power is not supplied to the vehicle), and therefore power consumption of the system can be suppressed.

The determiner 37 performs a determination step in the remaining lifetime estimating method according to the present embodiment. The determiner 37 determines whether or not the remaining use time Tx corrected by the corrector 34 is equal to or less than a predetermined value. The predetermined value is set to, for example, 0. However, the predetermined value is not limited to 0, and may be set to a value greater than 0.

The notifier 38 performs a notification step in the remaining lifetime estimating method according to the present embodiment. The notifier 38 issues a notification regarding the lifetime of the airbag 10 when the determiner 37 has determined the corrected remaining use time Tx to be equal to or less than the predetermined value. Specifically, the notifier 38 outputs a light signal to the airbag warning light 40. In this way, the lighting of the airbag warning light 40 notifies a user that the airbag 10 has reached the end of its remaining lifetime, making it possible to induce the user to repair or replace the airbag 10, ensuring safety.

Next, the process of the remaining lifetime estimating method performed by the remaining lifetime estimating system 2 according to the present embodiment having the aforementioned features is described in detail.

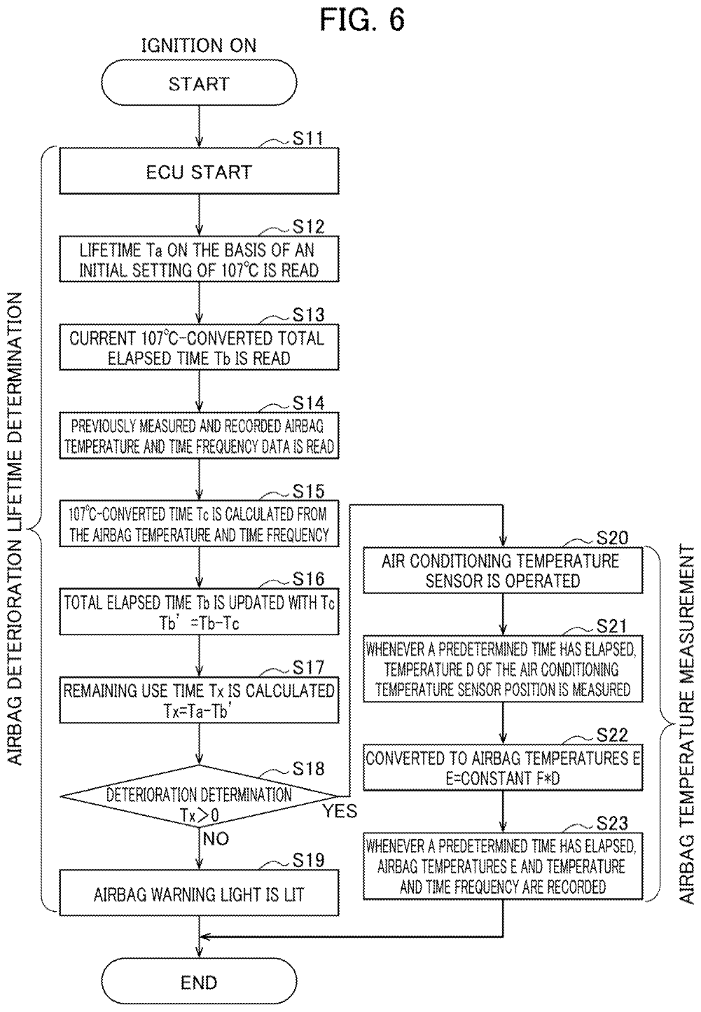

FIG. 6 is a flowchart illustrating a sequence of processes of the remaining lifetime estimating system 2 according to an embodiment of the present invention when the ignition is turned ON. As illustrated in FIG. 6, when the ignition of the vehicle 1 is turned ON (when power is supplied to the vehicle), an airbag deterioration lifetime determination process and an airbag temperature measurement process are performed.

At Step S11, in response to the ignition of the vehicle 1 having been turned ON, the ECU 30 is started. Thereafter, the process advances to Step S12.

At Step S12, a lifetime Ta on the basis of an initial setting of 107° C. is read. The lifetime Ta is obtained in advance according to, for example, a formula based on the Arrhenius equation, and is stored in the storage of the ECU 30. Thereafter, the process advances to Step S13.

At Step S13, a current 107° C.-converted total elapsed time Tb is read. The 107° C.-converted total elapsed time Tb is obtained by converting the total elapsed time from the start of a first-time use of the airbag 10 into the total elapsed time Tb from the start of a first-time use of the airbag 10 at 107° C., according to a formula based on the Arrhenius equation. Thereafter, the process advances to Step S14.

At Step S14, previously measured and recorded temperature and time frequency data of the airbag 10 is read. Specifically, a temperature and use time at this temperature of the airbag 10 when power was supplied to the vehicle 1 (temperature and time frequency data), which has been acquired and stored in the storage of the ECU 30 when the process was performed last time, is read. Thereafter, the process advances to Step S15.

At Step S15, the predetermined value Tc, which is the 107° C.-converted time, is calculated from the temperature and time frequency data of the airbag 10. Specifically, the predetermined value Tc is acquired by converting the use time at the temperature of the airbag 10 when power is supplied to the vehicle 1, using this temperature, into a use time at 107° C., according to a formula based on the Arrhenius equation. Thereafter, the process advances to Step S16.

At Step S16, the current 107° C.-converted total elapsed time Tb is updated using the predetermined value Tc calculated and acquired at Step S15. Specifically, an updated current 107° C.-converted total elapsed time Tb′ is acquired by subtracting the predetermined value Tc from the current 107° C.-converted total elapsed time Tb. Thereafter, the process advances to Step S17.

At Step S17, a remaining use time Tx is calculated. Specifically, the remaining use time Tx of the airbag 10 is acquired by subtracting the total elapsed time Tb′ acquired at Step S16 from the lifetime Ta of the airbag 10 at 107° C. Thereafter, the process advances to Step S18.

At Step S18, it is determined whether the airbag 10 has deteriorated. Specifically, it is determined whether or not the remaining use time Tx of the airbag 10 acquired at Step S17 is greater than 0. If the result is NO, the process advances to Step S19, and if the result is YES, the process advances to Step S20.

At Step S19, because the result of Step S18 was NO and the airbag 10 has reached the end of its lifetime, the airbag warning light 40 is lit, and the process ends.

At Step S20, because the result of Step S18 was YES and the airbag 10 has not yet reached the end of its lifetime, the air conditioning temperature sensor 20 is operated in order to acquire temperature and time frequency data. Thereafter, the process advances to Step S21.

At Step S21, whenever a predetermined time has elapsed, a temperature D of the air conditioning temperature sensor 20 is measured and acquired. Thereafter, the process advances to Step S22.

At Step S22, conversion into temperatures E of the airbag 10 when power is supplied to the vehicle 1 is performed. Specifically, the temperatures E of the airbag 10 when power is supplied to the vehicle 1 are acquired by multiplying the temperature D of the air conditioning temperature sensor 20 acquired at Step S21 by constants F determined in advance for each airbag 10. Thereafter, the process advances to Step S23.

At Step S23, whenever a predetermined time has elapsed, the temperatures E of the airbag 10 acquired at Step S22 and the temperature and time frequency data are recorded, and the process ends.

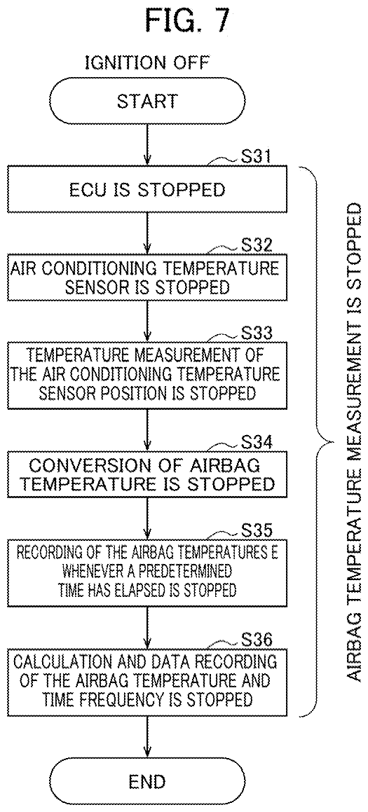

FIG. 7 is a flowchart illustrating a sequence of processes of the remaining lifetime estimating system 2 according to an embodiment of the present invention when the ignition is turned OFF. As illustrated in FIG. 7, when the ignition of the vehicle 1 is turned OFF (when the vehicle is parked), an airbag temperature measurement stopping process is performed.

At Step S31, in response to the ignition of the vehicle 1 having been turned OFF, the ECU 30 is stopped. Thereafter, the process advances to Step S32.

At Step S32, operation of the air conditioning temperature sensor 20 is stopped. Thereafter, the process advances to Step S33.

At Step S33, temperature measuring of the air conditioning sensor 20 is stopped. Thereafter, the process advances to Step S34.

At Step S34, conversion into the temperatures E of the airbag 10 is stopped. Thereafter, the process advances to Step S35.

At Step S35, recording of the temperatures E of the airbag 10 whenever a predetermined time has elapsed is stopped. Thereafter, the process advances to Step S36.

At Step S36, calculation and recording of the temperature and time frequency data of the airbag 10 is stopped, and the process ends.

Described next is an example of the remaining lifetime estimating method by the remaining lifetime estimating system 2 according to the present embodiment put into practice.

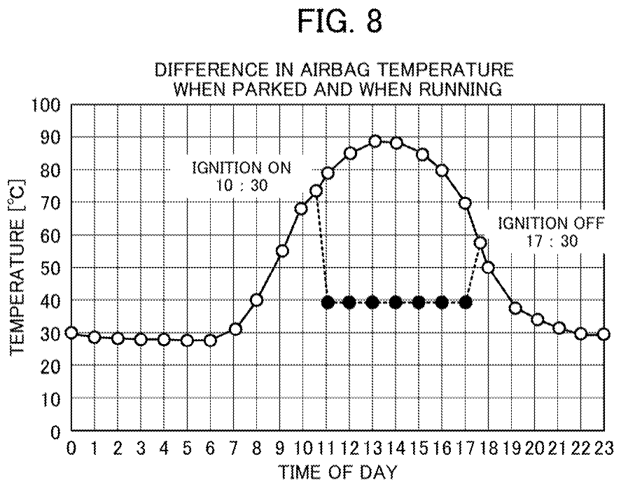

FIG. 8 illustrates a difference in temperature of the airbag 10 between when the vehicle is parked and when the vehicle is running. In FIG. 8, the X-axis represents a time of day and the Y-axis represents a temperature. The white circles in FIG. 8 indicate the temperature of the airbag 10 when the vehicle is parked, and the black circles indicate the temperature of the airbag 10 when the vehicle is running (when power is supplied to the vehicle). When the vehicle has been parked all day, the temperature of the airbag 10 follows the trajectory of the white circles and reaches its peak of about 90° C. at around 13:00 to 14:00. On the other hand, when the vehicle is running, such as, for example, when the ignition is turned ON at 10:30 as illustrated in FIG. 8, the temperature of the airbag 10 will shift from the trajectory of the white circles to the trajectory of the black circles, and will be kept at about 40° C.

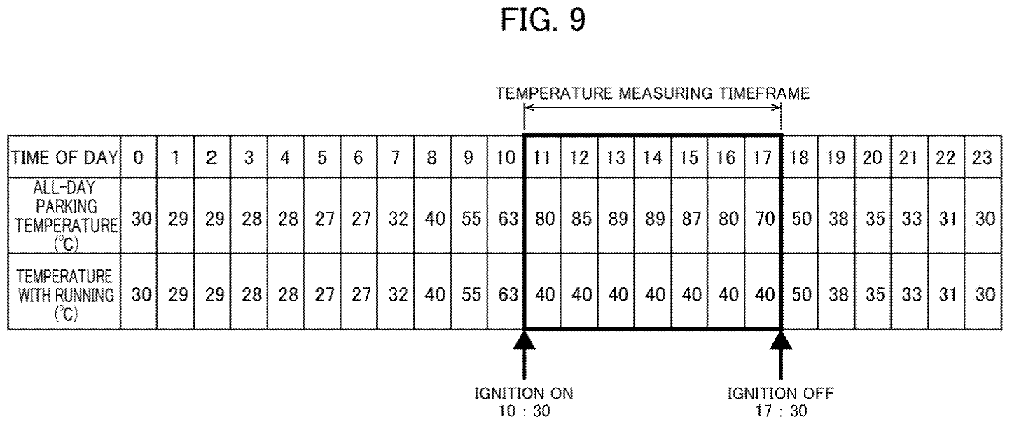

FIG. 9 illustrates temperatures when the vehicle has been parked all day and when the vehicle has been running. Specifically, FIG. 9 illustrates temperature data for each time of day in the temperature curve of FIG. 8. As described above, with the remaining lifetime estimating method by the remaining lifetime estimating system 2 according to the present embodiment, the temperature of the airbag 10 and the use time at that temperature (temperature and time frequency data) is acquired whenever a predetermined time has elapsed when power is supplied to the vehicle 1, that is to say, when the ignition is turned ON. In the present example, the temperature and time frequency data of the airbag 10 is measured and acquired during a period from 10:30 when the ignition is turned ON to 17:30 when the ignition is turned off, more specifically once per hour, at 11:00, 12:00, 13:00, 14:00, 15:00, 16:00, and 17:00.

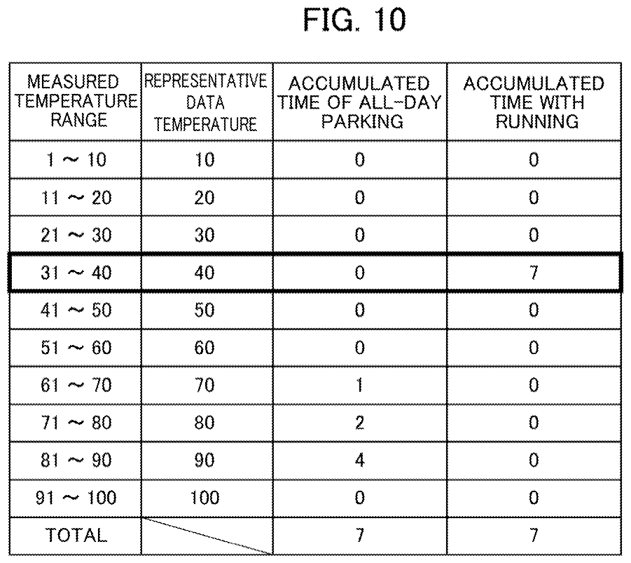

FIG. 10 illustrates accumulated hours at measured temperatures when the vehicle has been parked all day and when the vehicle has been running. Specifically, FIG. 10 is a histogram of the temperature measurement data from 11:00 to 17:00 in FIG. 8 and FIG. 9. From FIG. 10, it can be seen that the temperature of the airbag 10 when the vehicle is running (when power is supplied to the vehicle) is 40° C., and that the accumulated hours at 40° C. is 7 hours.

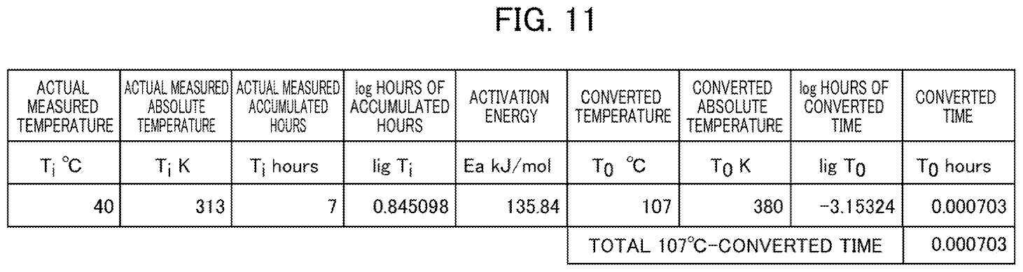

FIG. 11 explains a time conversion based on the Arrhenius equation. As illustrated in FIG. 11, by calculating a converted time at 107° C. (absolute temperature of 380 K) according to Formula (1) based on the Arrhenius equation from an actual measured temperature of 40° C. (absolute temperature of 313 K), actual accumulated hours of 7 hours (0.845098 log hours), and an activation energy of 135.84 kJ/mol of the airbag 10 using PA66 of the present example, it can be seen that the converted time is 0.000703 hours.

Accordingly, in the present example, the converted time at 107° C. of 0.000703 hours, calculated as exemplarily described above, is added to the lifetime set in advance on the basis of a temperature when parked (maximum temperature of 90° C.), so as to increase the remaining use time. Thus, when the vehicle is running (when power is supplied to the vehicle), and operation of air conditioning, etc. lowers an interior temperature of the vehicle, slowing down deterioration of the airbag, it is possible to perform a correction to increase the remaining use time accordingly, thereby extending the remaining lifetime.

The remaining lifetime estimating system 2 and the remaining lifetime estimating method according to the present embodiment exhibit the following effects.

(1) According to the remaining lifetime estimating system 2 and the remaining lifetime estimating method according to the present embodiment, whenever a predetermined time has elapsed, the total elapsed time from the start of a first-time use of the airbag 10 is converted into the total elapsed time Tb from the start of the first-time use of the airbag 10 at a predetermined temperature t, according to a formula based on the Arrhenius equation. In addition, the remaining use time Tx of the subject is calculated by subtracting the total elapsed time Tb from a lifetime Ta of the airbag 10 at the predetermined temperature t. Then, a correction to increase the remaining use time Tx is performed on the basis of a predetermined value Tc proportional to a power supply time to the vehicle 1. In other words, according to the remaining lifetime estimating method according to the present embodiment, because deterioration of the airbag 10 slows down when power is supplied to the vehicle 1 due to operation of air conditioning, etc., the remaining use time Tx is first calculated on the basis of the Arrhenius equation, and the correction is performed to increase the remaining use time Tx on the basis of the predetermined value Tc that is acquired by measuring a temperature when power is supplied to the vehicle 1 whenever a predetermined time has elapsed.

Thus, the correction to increase the remaining use time is performed on the basis of the temperature and use time of the airbag 10 in actual use, and therefore the remaining lifetime of the airbag 10 can be estimated precisely. Therefore, the usable time of the airbag 10 can be established precisely, which as a result allows for an extension of the remaining lifetime during which safe use is possible. In addition, the correction is performed when power is supplied to the vehicle 1, and therefore, unlike Patent Document 1, there is no need to measure the temperature whenever a predetermined time has elapsed even when the system is not operating in order to address deterioration over time. Therefore, according to the remaining lifetime estimating system 2 and the remaining lifetime estimating method according to the present embodiment, it is possible to precisely estimate the remaining lifetime of the airbag 10, while suppressing the power consumption of the system.

(2) According to the remaining lifetime estimating system 2 and the remaining lifetime estimating method according to the present embodiment, the remaining use time Tx can be increased by adding the predetermined value Tc to extend the lifetime Ta. Therefore, the effect as in the above (1) can be achieved more reliably.

(3) According to the remaining lifetime estimating system 2 and the remaining lifetime estimating method according to the present embodiment, the predetermined value Tc is set to be greater the lower the temperature of the airbag 10 when power is supplied to the vehicle 1. Therefore, deterioration over time of the airbag 10 is more suppressed the lower the temperature, allowing for further improvement of the estimation precision of the remaining lifetime.

(4) According to the remaining lifetime estimating system 2 and the remaining lifetime estimating method according to the present embodiment, whenever a predetermined time has elapsed, the correction to increase the remaining use time Tx is performed on the basis of the predetermined value Tc acquired by converting the use time at a temperature of the airbag 10 when power is supplied to the vehicle 1 into a use time at the predetermined temperature t according to a formula based on the Arrhenius equation. Therefore, the remaining use time Tx can be corrected on the same scale as the total elapsed time Tb, making it possible to more precisely estimate the remaining lifetime.

(5) According to the remaining lifetime estimating system 2 and the remaining lifetime estimating method according to the present embodiment, the conversion into the total elapsed time Tb from the start of the first-time use of the airbag 10 at the predetermined temperature t based on the Arrhenius equation is performed when power starts to be supplied to the vehicle 1. Likewise, the predetermined value Tc obtained by the conversion into the use time at the predetermined temperature t based on the Arrhenius equation is acquired when power starts to be supplied to the vehicle 1. Further, the acquisition of the temperature of the airbag 10 and the use time at that temperature when power is supplied to the vehicle 1 is performed after determination regarding deterioration, and is continuously performed until power stops being supplied to the vehicle 1. Thus, when the vehicle 1 is not operating, there is no need to count the temperature and time, and therefore the power consumption of the system can be more reliably suppressed. Consequently, because the temperature of the airbag 10 is measured only when power is supplied to the vehicle 1 (when the ignition is turned ON), measurement of the temperature of the airbag 10 is stopped when the vehicle is parked (when the ignition is turned OFF), eliminating dark current draw by measurement while the vehicle is parked, preventing the battery from running out.

(6) According to the remaining lifetime estimating system 2 and the remaining lifetime estimating method according to the present embodiment, temperatures of a plurality of airbags 10 when power is supplied to the vehicle 1 are acquired by multiplying a detected value of an air conditioning temperature sensor 20 installed in the vehicle 1 by constants determined in advance. Therefore, there is no need to provide a plurality of temperature sensors, which makes it possible to reduce costs. In the aforementioned Patent Document 1, the temperature of the capacitor is measured directly, and therefore a number of temperature sensors are required depending on the number of capacitors. With the remaining lifetime estimating system 2 and the remaining lifetime estimating method as in the above (6), however, this can be avoided with certainty.

In addition, the vehicle 1 provided with the remaining lifetime estimating system 2 according to the present embodiment also achieves the effects of the above (1) to (6). In particular, because the air conditioning temperature sensor 20 that the vehicle 1 is already provided with can be used, lifetime estimation of the airbag 10 is possible without adding sensors, which reduces costs. Further, because the method can be applied to remaining lifetime estimation of driver's seat airbag components and passenger's seat airbag components, an effect of ensuring safety of these airbags can be achieved.

It should be noted that the present invention is not limited to the above embodiment, and that variations and modifications within a scope capable of achieving the object of the present invention are included in the present invention. In the above embodiment, the subject of which the remaining lifetime is estimated is an airbag 10 arranged in an interior of a vehicle 1, but the subject is not so limited. For example, in addition to vehicle body components other than power components and drive components, various electronic components installed in various devices are also applicable.

### EXPLANATION OF REFERENCE NUMERALS

1 Vehicle (device)
2 Remaining lifetime estimating system
10 Airbag (subject)
11 Driver's seat airbag (subject)
12 Passenger's seat airbag (subject)
13 Driver's seat side airbag (subject)
14 Passenger's seat side airbag (subject)
20 Air conditioner temperature sensor (reference temperature sensor)
21, 22, 23, 34 Airbag temperature measuring points
30 ECU
31 Remaining lifetime estimator
32 Converter
33 Remaining use time calculator
34 Corrector
35 Acquirer
36 Correction processor
37 Determiner
38 Notifier
40 Airbag warning light
110 Bag fabric
111 Airbag cover
112 Gas generant
113 Igniting agent
114 Explosive
115 Connector
116 Harness
117 Squib body
118 O-ring
119 Sealing tape

What is claimed is:

1. A remaining lifetime estimating method for estimating a remaining lifetime of a subject installed in a device, the method comprising:
a conversion step of, whenever a predetermined time has elapsed, converting a total elapsed time from a start of a first-time use of the subject into a total elapsed time Tb from the start of the first-time use of the subject at a predetermined temperature t, according to a formula based on the Arrhenius equation;
a remaining use time calculation step of calculating a remaining use time Tx of the subject by subtracting the total elapsed time Tb from a lifetime Ta of the subject at the predetermined temperature t;
a correction step of performing a correction to increase the remaining use time Tx on the basis of a predetermined value Tc proportional to a power supply time to the device;
a determination step of determining whether or not the remaining use time Tx corrected in the correction step is equal to or less than a predetermined value; and
a notification step of issuing a notification regarding the lifetime of the subject when it has been determined in the determination step that the corrected remaining use time Tx is equal to or less than the predetermined value.

2. The remaining lifetime estimating method according to claim 1, wherein in the correction step, the correction to increase the remaining use time Tx is performed by adding the predetermined value Tc to extend the lifetime Ta.

3. The remaining lifetime estimating method according to claim 1, wherein the predetermined value Tc is greater the lower the temperature of the subject when power is supplied to the device.

4. The remaining lifetime estimating method according to claim 1, wherein the correction step has:
an acquisition step of, whenever a predetermined time has elapsed, acquiring a temperature of the subject and a use time at that temperature when power is supplied to the device; and
a correction processing step of, whenever a predetermined time has elapsed, acquiring the predetermined value Tc by converting the acquired use time using the acquired temperature into a use time at the predetermined temperature t according to a formula based on the Arrhenius equation, and, on the basis of the predetermined value Tc, performing the correction to increase the remaining use time Tx.

5. The remaining lifetime estimating method according to claim 4, wherein the conversion step and the correction processing step are performed when power starts to be supplied to the device, and
the acquisition step is performed after determination by the determination step, and is continuously performed until power stops being supplied to the device.

6. The remaining lifetime estimating method according to claim 4, wherein a plurality of the subjects are installed in the device, and
in the acquisition step, temperatures of the plurality of subjects when power is supplied to the device are acquired by multiplying a detected value of a reference temperature sensor installed in the device by constants determined in advance.

7. A remaining lifetime estimating system for estimating a remaining lifetime of a subject installed in a device, the remaining lifetime estimating system comprising:
a converter configured to, whenever a predetermined time has elapsed, convert a total elapsed time from a start of a first-time use of the subject into a total elapsed time Tb from the start of the first-time use of the subject at a predetermined temperature t, according to a formula based on the Arrhenius equation;
a remaining use time calculator configured to calculate a remaining use time Tx of the subject by subtracting the total elapsed time Tb from a lifetime Ta of the subject at the predetermined temperature t;
a corrector configured to perform a correction to increase the remaining use time Tx on the basis of a predetermined value Tc proportional to a power supply time to the device;
a determiner configured to determine whether or not the remaining use time Tx corrected in the correction step is equal to or less than a predetermined value; and
a notifier configured to issue a notification regarding the lifetime of the subject when it has been determined in the determination step that the corrected remaining use time Tx is equal to or less than the predetermined value.

8. The remaining lifetime estimating system according to claim 7, wherein the corrector performs the correction to increase the remaining use time Tx by adding the predetermined value Tc to extend the lifetime Ta.

9. The remaining lifetime estimating system according to claim 7, wherein the predetermined value Tc is greater the lower the temperature of the subject when power is supplied to the device.

10. The remaining lifetime estimating system according to claim 7, wherein the corrector has:
an acquirer configured to, whenever a predetermined time has elapsed, acquire a temperature of the subject and a use time at that temperature when power is supplied to the device; and
a correction processor configured to, whenever a predetermined time has elapsed, acquire the predetermined value Tc by converting the acquired use time using the acquired temperature into a use time at the predetermined temperature t according to a formula based on the Arrhenius equation, and, on the basis of the predetermined value Tc, perform the correction to increase the remaining use time Tx.

11. The remaining lifetime estimating system according to claim 10, wherein the converter performs the conversion when power starts to be supplied to the device,
the correction processor performs the correction when power starts to be supplied to the device, and
the acquirer performs the acquisition after determination by the determiner, and continuously performs the acquisition until power stops being supplied to the device.

12. The remaining lifetime estimating system according to claim 10, wherein a plurality of the subjects are installed in the device, and
the acquirer acquires temperatures of the plurality of subjects when power is supplied to the device by multiplying a detected value of a reference temperature sensor installed in the device by constants determined in advance.

13. A vehicle comprising the remaining lifetime estimating system according to claim 12, wherein
the subject is a vehicle body component, and
the reference temperature sensor is an air conditioning temperature sensor.

14. The vehicle according to claim 13, wherein the subject is a driver's seat airbag component and/or a passenger's seat airbag component.
